(19) United States
(12) Patent Application Publication
(10) Pub. No.: US 2010/0194407 A1
(43) Pub. Date: Aug. 5, 2010

(54) MEMS sensor

(75) Inventor: Goro Nakatani, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/656,442

(22) Filed: Jan. 29, 2010

(30) Foreign Application Priority Data
Jan. 30, 2009 (JP) 2009-020990

(51) Int. Cl. G01R 27/26

(52) U.S. Cl. 324/660

(57) ABSTRACT

The MEMS sensor according to the present invention includes: a substrate made of a silicon material, having a recess dug down from the surface thereof; a fixed electrode made of a metallic material, arranged in the recess and fixed to the substrate; and a movable electrode made of a metallic material, arranged in the recess to be opposed to the fixed electrode and provided to be displaceable with respect to the fixed electrode.

### BACKGROUND OF THE INVENTION

1. Field of the Invention

The present invention relates to a sensor manufactured by the MEMS (Micro Electro Mechanical Systems) technique.

2. Description of Related Art

An MEMS sensor has recently been increasingly watched with interest. For example, an acceleration sensor for detecting acceleration of an object is known as a typical MEMS sensor.

A conventional acceleration sensor is manufactured with an SOI (Silicon On Insulator) substrate. The SOI substrate has a structure obtained by stacking a BOX (Buried Oxide) layer made of SiO₂ (silicon oxide) and a silicon layer in this order on a silicon substrate, for example. The silicon layer is doped with a P-type impurity or an N-type impurity in a high concentration, and has high conductivity (low resistance).

The acceleration sensor includes a fixed electrode and a movable electrode. The fixed electrode and the movable electrode are provided in the form of plates extending in the thickness direction of the silicon layer and a direction orthogonal thereto respectively by patterning the silicon layer of the SOI substrate, and parallelly provided at a small interval. The fixed electrode is supported by the silicon substrate through the BOX layer. The BOX layer is partially removed from under the movable electrode, so that the movable electrode floats up from the silicon substrate.

The fixed electrode and the movable electrode constitute a capacitor for detecting acceleration in an opposed direction thereof (simply referred to as an “opposed direction” in this section), for example. When acceleration in the opposed direction acts on the acceleration sensor (an object loaded with the acceleration sensor), the movable electrode is displaced in the opposed direction, to change the interval between the fixed electrode and the movable electrode. The capacitance of the capacitor constituted of the fixed electrode and the movable electrode is changed following the change in the interval between the fixed electrode and the movable electrode, and hence the magnitude of the acceleration in the opposed direction acting on the acceleration sensor can be detected on the basis of the change in the capacitance.

### SUMMARY OF THE INVENTION

However, the SOI substrate is relatively high-priced, and hence the conventional acceleration sensor requires a high cost.

Further, the silicon layer has high conductivity, and hence the conventional acceleration sensor requires an isolation layer for electrically isolating the region provided with the fixed electrode and the movable electrode from the periphery. The isolation layer has a structure obtained by embedding an insulating material in an annular trench surrounding the periphery of the region provided with the fixed electrode and the movable electrode, for example. If the isolation layer is unnecessary, the size of the acceleration sensor can be reduced by that occupied by the isolation layer. Further, a step for forming the isolation layer is omitted, whereby the number of photomasks (the number of layers) employed for manufacturing the acceleration sensor can be reduced.

An object of the present invention is to provide an MEMS sensor manufacturable without employing an SOI substrate and requiring no isolation layer.

The foregoing and other objects, features and effects of the present invention will become more apparent from the following detailed description of the embodiments with reference to the attached drawings.

### BRIEF DESCRIPTION OF THE DRAWINGS

FIG. 1 is a plan view of an acceleration sensor according to a first embodiment of the present invention, illustrating an electrode structure.

FIG. 2 is a schematic sectional view of the acceleration sensor taken along a line II-II in FIG. 1.

FIGS. 3A to 3Q are schematic sectional views for illustrating a method of manufacturing the acceleration sensor shown in FIG. 2.

FIG. 4 is a schematic sectional view showing a portion around side surfaces of a fixed electrode and a movable electrode in an enlarged manner.

FIG. 5 is a schematic sectional view of a silicon microphone according to a second embodiment of the present invention.

FIGS. 6A to 6Q are schematic sectional views for illustrating a method of manufacturing the silicon microphone shown in FIG. 5.

### DETAILED DESCRIPTION OF PREFERRED EMBODIMENTS

An MEMS sensor according to an embodiment of the present invention includes: a substrate made of a silicon material, having a recess dug down from the surface thereof; a fixed electrode made of a metallic material, arranged in the recess and fixed to the substrate; and a movable electrode made of a metallic material, arranged in the recess to be opposed to the fixed electrode and provided to be displaceable with respect to the fixed electrode.

In the MEMS sensor, the recess is formed in the substrate, so that the fixed electrode and the movable electrode are arranged in the recess. The fixed electrode and the movable electrode are made not of the silicon material forming the substrate but of the metallic materials, and not formed by patterning the substrate. Therefore, the substrate may not be highly conductive. Thus, the MEMS sensor can be manufactured with a silicon substrate of low conductivity (high resistance) doped with no impurity, without employing an SOI substrate including a highly conductive silicon layer.

The substrate is not highly conductive, whereby the region provided with the fixed electrode and the movable electrode may not be isolated from the periphery thereof. Therefore, no isolation layer is required for such isolation. Consequently, the size of the MEMS sensor can be reduced by that occupied by an isolation layer. Further, a step for forming the isolation layer can be omitted, and the steps of manufacturing the MEMS sensor can be simplified. In addition, no photomask for forming the isolation layer is required, whereby the number of photomasks employed for manufacturing the MEMS sensor can be reduced.

The fixed electrode and the movable electrode may be in the form of plates extending in the depth direction of the recess and a direction orthogonal thereto, and may be opposed to each other in a direction parallel to the surface of the substrate. In this case, the fixed electrode and the movable electrode made of the metallic materials can be easily formed by digging down a groove for forming the fixed electrode and a groove for forming the movable electrode in the substrate from the surface thereof, depositing the metallic materials in the grooves respectively and thereafter partially removing the substrate from the space between the grooves.

Preferably, a surface of the fixed electrode opposed to the movable electrode and a surface of the movable electrode opposed to the fixed electrode are covered with an insulating film. Thus, a short circuit resulting from contact between the fixed electrode and the movable electrode can be prevented.

More preferably, undulate irregularities are formed on the surface of the insulating film. Thus, the irregularities on the surface of the insulating film function as stabilizers for the movable electrode when the movable electrode is displaced (vibrated), and the movable electrode can be prevented from sticking to the fixed electrode. When the fixed electrode and the movable electrode having the insulating film on the surfaces thereof are formed by forming the groove for forming the fixed electrode and the groove for forming the movable electrode in the substrate and depositing the metallic materials in the grooves through the insulating film, the grooves are so formed by a Bosch process that scallops are formed on the side surfaces of the grooves, whereby the irregularities are necessarily formed on the surface of the insulating film.

The movable electrode may include a first movable electrode displaced in an opposed direction to the fixed electrode for detecting acceleration in the opposed direction. The fixed electrode and the first movable electrode constitute a capacitor for detecting acceleration in the opposed direction thereof, and the magnitude of the acceleration in the opposed direction can be detected on the basis of a change in the capacitance of the capacitor.

The movable electrode may include a second movable electrode displaced in the depth direction of the recess for detecting acceleration in the depth direction. The fixed electrode and the second movable electrode constitute a capacitor for detecting acceleration in the depth direction of the recess, and the magnitude of the acceleration in the depth direction can be detected on the basis of a change in the capacitance of the capacitor.

Further, a metallic material may be bonded to a surface of the second movable electrode opposite to a surface opposed to the bottom surface of the recess, and the position of the second movable electrode may deviate from the fixed electrode in the depth direction. When the second movable electrode is displaced from the state deviating from the fixed electrode, the direction of acceleration can be detected depending on whether the capacitance of the capacitor constituted of the fixed electrode and the second movable electrode is increased or decreased.

The movable electrode may be displaced in an opposed direction to the fixed electrode, for detecting a sound wave incident upon the recess. The fixed electrode and the movable electrode constitute a capacitor for detecting a sound wave, and the strength and the frequency of the sound wave can be detected on the basis of a change in the capacitance of the capacitor.

In this case, a sound wave reflecting space communicating with the recess is preferably formed on a side closer to a base layer of the substrate than the recess. The sound wave reflecting space is so formed that a sound wave incident upon the sound wave reflecting space through the recess can be reflected on the inner surface thereof and the reflected wave can be introduced into the movable electrode. Therefore, the sound wave can be more excellently detected.

Preferably, the materials for the fixed electrode and the movable electrode are tungsten. In this case, tungsten can be deposited in the grooves by either plating or CVD (Chemical Vapor Deposition), after the groove for forming the fixed electrode and the groove for forming the movable electrode are formed in the substrate.

Embodiments of the present invention are now described in detail with reference to the attached drawings.

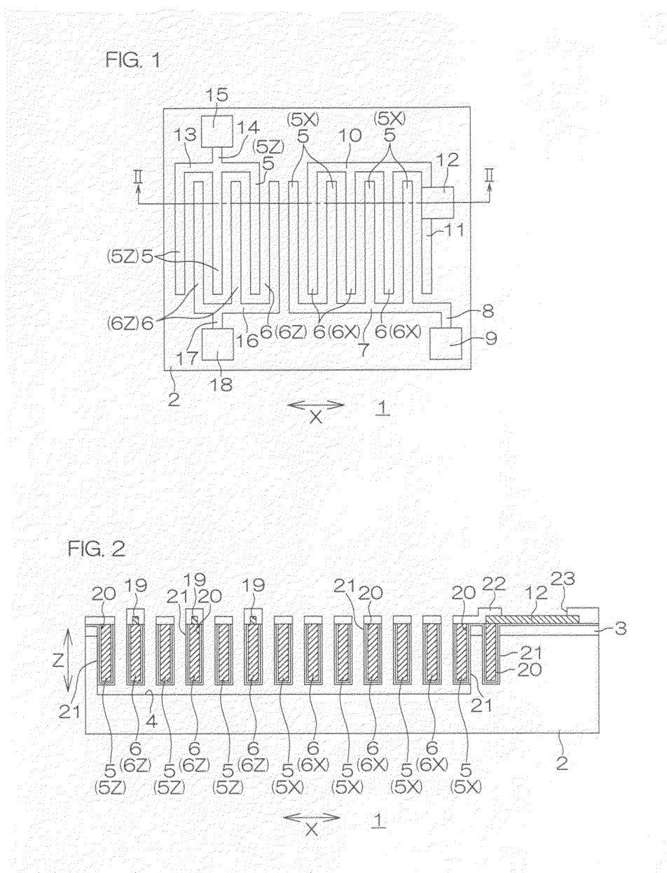

FIG. 1 is a plan view of an acceleration sensor according to a first embodiment of the present invention, illustrating an electrode structure. FIG. 2 is a schematic sectional view of the acceleration sensor taken along a line II-II in FIG. 1.

An acceleration sensor 1 according to the first embodiment is a sensor (an MEMS sensor) manufactured by the MEMS technique.

As shown in FIG. 2, the acceleration sensor 1 includes a silicon substrate 2 quadrangular in plan view. The silicon substrate 2 is a high-resistance (low-conductivity) substrate doped with no impurity.

An insulating layer 3 made of SiO₂ is formed on a surface layer portion of the silicon substrate 2.

A recess 4 quadrangular in plan view is formed in the substrate 2. The recess 4 is dug down from the surface of the insulating layer 3.

A plurality of fixed electrodes 5 and a plurality of movable electrodes 6 are provided in the recess 4. The fixed electrodes 5 and the movable electrodes 6 are made of W (tungsten), and provided in the form of plates extending in the depth direction of the recess 4 and a direction orthogonal thereto respectively. The fixed electrodes 5 and the movable electrodes 6 are opposed to one another in an X-axis direction parallel to the surface of the silicon substrate 2 at small intervals. The fixed electrodes 5 and the movable electrodes 6 are alternately arranged in the X-axis direction.

A plurality of fixed electrodes 5X and a plurality of movable electrodes 6X from one side (the right side in FIGS. 1 and 2) in the X-axis direction constitute a capacitor for detecting acceleration in the X-axis direction.

As shown in FIG. 1, the fixed electrodes 5X for detecting the acceleration in the X-axis direction are fixedly provided with respect to the silicon substrate 2, in a state floating up from the silicon substrate 2. Single end portions of the fixed electrodes 5X are coupled with one another by a coupling portion 7 made of the same metallic material as the fixed electrodes 5X. Thus, the fixed electrodes 5X and the coupling portion 7 form an interdigital structure having teeth defined by the fixed electrodes 5X. A drawn portion 8 embedded in the silicon substrate 2 is connected to the coupling portion 7. The drawn portion 8 is formed integrally with the coupling portion 7. The drawn portion 8 is connected to a pad 9 provided on the insulating layer 3 from under the same.

The movable electrodes 6X for detecting the acceleration in the X-axis direction are provided to be vibratile in the X-axis direction, in a state floating up from the silicon substrate 2. Single end portions of the movable electrodes 6X are coupled with one another by a coupling portion 10 made of the same metallic material as the movable electrodes 6X. The coupling portion 10 is provided on a side of the movable electrodes 6X opposite to the coupling portion 7. Thus, the movable electrodes 6X and the coupling portion 10 form an interdigital structure having teeth defined by the movable electrodes 6X and meshing with the interdigital structure formed by the fixed electrodes 5X and the coupling portion 7 without bringing the teeth thereof into contact with one another. A drawn portion 11 embedded in the silicon substrate 2 is connected to the coupling portion 10. The drawn portion 11 is formed integrally with the coupling portion 10. The drawn portion 11 is connected to a pad 12 provided on the insulating layer 3 from under the same.

The remaining fixed electrodes 5Z and the remaining movable electrodes 6Z constitute a capacitor for detecting acceleration in a Z-axis direction perpendicular to the surface of the silicon substrate 2.

The fixed electrodes 5Z for detecting the acceleration in the Z-axis direction are fixedly provided with respect to the silicon substrate 2, in a state floating up from the silicon substrate 2 (the bottom surface of the recess 4). Single end portions of the fixed electrodes 5Z are coupled with one another by a coupling portion 13 made of the same metallic material as the fixed electrodes 5Z. Thus, the fixed electrodes 5Z and the coupling portion 13 form an interdigital structure having teeth defined by the fixed electrodes 5Z. A drawn portion 14 embedded in the silicon substrate 2 is connected to the coupling portion 13. The drawn portion 14 is formed integrally with the coupling portion 13. The drawn portion 14 is connected to a pad 15 provided on the insulating layer 3 from under the same.

The movable electrodes 6Z for detecting the acceleration in the Z-axis direction are provided to be vibratile in the Z-axis direction, in a state floating up from the silicon substrate 2. Single end portions of the movable electrodes 6Z are coupled with one another by a coupling portion 16 made of the same material as the movable electrodes 6Z. The coupling portion 16 is provided on a side of the movable electrodes 6Z opposite to the coupling portion 13. Thus, the movable electrodes 6Z and the coupling portion 16 form an interdigital structure having teeth defined by the movable electrodes 6Z and meshing with the interdigital structure formed by the fixed electrodes 5Z and the coupling portion 13 without bringing the teeth thereof into contact with one another. A drawn portion 17 embedded in the silicon substrate 2 is connected to the coupling portion 16. The drawn portion 17 is formed integrally with the coupling portion 16. The drawn portion 17 is connected to a pad 18 provided on the insulating layer 3 from under the same.

The pads 9, 12, 15 and 18 are made of a metallic material (Al (aluminum), for example), and quadrangular in plan view.

As shown in FIG. 2, metallic materials 19 identical to the material for the pads 9, 12, 15 and 18 are bonded onto the movable electrodes 6Z respectively. Due to the tensile difference between the metallic materials 19 and the movable electrodes 6Z, the movable electrodes 6Z are warped and deformed to be convex toward the side of the silicon substrate 2, and the positions thereof slightly deviate from the fixed electrodes 5Z upward in the Z-axis direction (in a direction separating from the silicon substrate 2), although this state is not illustrated in FIG. 2. The side surfaces and the lower surfaces of the fixed electrodes 5, the movable electrodes 6, the coupling portions 7, 10, 13 and 16 and the drawn portions 8, 11, 14 and 17 are covered with a barrier film 20. The barrier film 20 is a multilayer film of Ti (titanium)/TiN (titanium nitride) or that of Ti/W, for example. The outer side of the barrier film 20 is covered with an insulating film 21. The insulating film 21 is made of SiO₂, for example.

A surface protective film 22 is stacked on the silicon substrate 2. The surface protective film 22 is made of SiN (silicon nitride), for example. Openings 23 for individually exposing the pads 9, 12, 15 and 18 are formed in the surface protective film 22, so that external wires (not shown) can be connected to the pads 9, 12, 15 and 18 through the openings 23 respectively.

When the acceleration in the X-axis direction acts on the acceleration sensor 1 (an object loaded with the acceleration sensor 1) and the movable electrodes 6X are displaced in the X-axis direction, the intervals between the fixed electrodes 5X and the movable electrodes 6X are changed, to change the capacitance of the capacitor constituted of the fixed electrodes 5X and the movable electrodes 6X. Due to the change in the capacitance, a current responsive to the change in the capacitance flows to the external wires connected to the pads 9 and 12 respectively. Therefore, the magnitude of the acceleration in the X-axis direction acting on the acceleration sensor 1 can be detected on the basis of the value of the current.

When the acceleration in the Z-axis direction acts on the acceleration sensor 1 and the movable electrodes 6Z are displaced in the Z-axis direction, opposed areas of the fixed electrodes 5Z and the movable electrodes 6Z are changed, to change the capacitance of the capacitor constituted of the fixed electrodes 5Z and the movable electrodes 6Z. The positions of the movable electrodes 6Z slightly deviate from the fixed electrodes 5Z upward in the Z-axis direction in the state not yet receiving the acceleration. When the movable electrodes 6Z are displaced downward in the Z-axis direction, therefore, the opposed areas of the fixed electrodes 5Z and the movable electrodes 6Z are increased, to increase the capacitance of the capacitor. When the movable electrodes 6Z are displaced upward in the Z-axis direction, on the other hand, the opposed areas of the fixed electrodes 5Z and the movable electrodes 6Z are reduced, to reduce the capacitance of the capacitor. Due to the change in the capacitance, a current responsive to the change in the capacitance flows to the external wires connected to the pads 15 and 18 respectively. Therefore, the direction and the magnitude of the acceleration in the Z-axis direction acting on the acceleration sensor 1 can be detected on the basis of the direction and the value of the current.

Fixed electrodes and movable electrodes opposed to one another in a Y-axis direction orthogonal to the X-axis direction and the Z-axis direction may be additionally provided, so that the direction and the magnitude of acceleration in the Y-axis direction acting on the acceleration sensor 1 can be detected on the basis of a change in the capacitance of a capacitor constituted of the fixed electrodes and the movable electrodes.

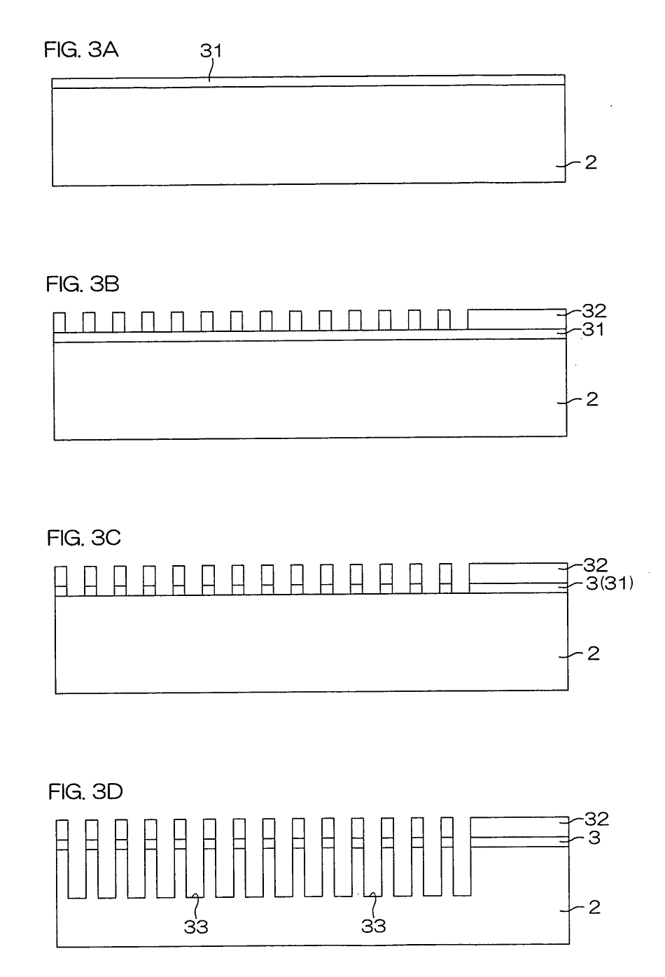

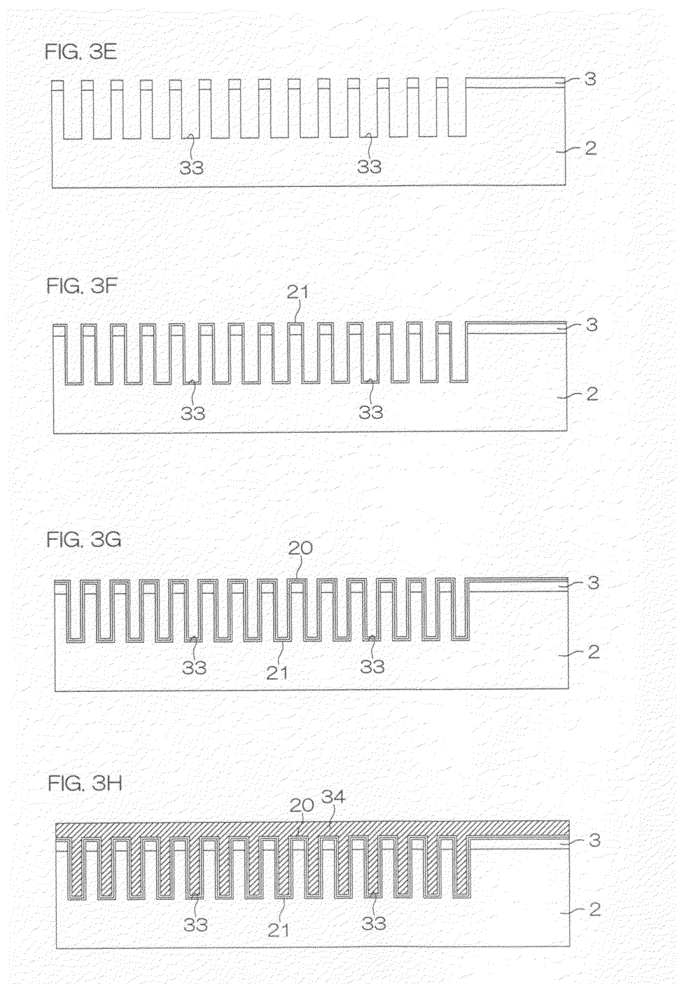

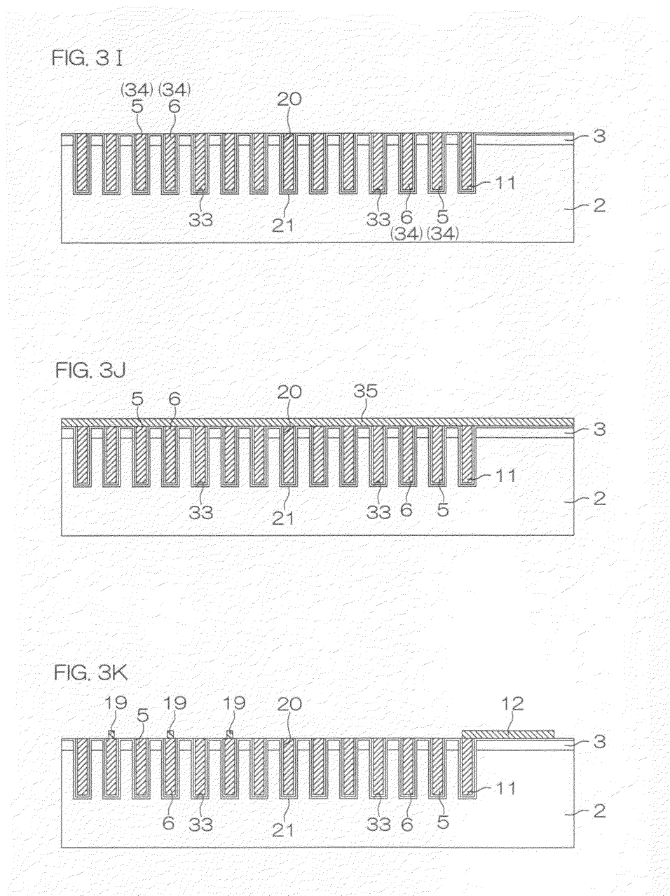

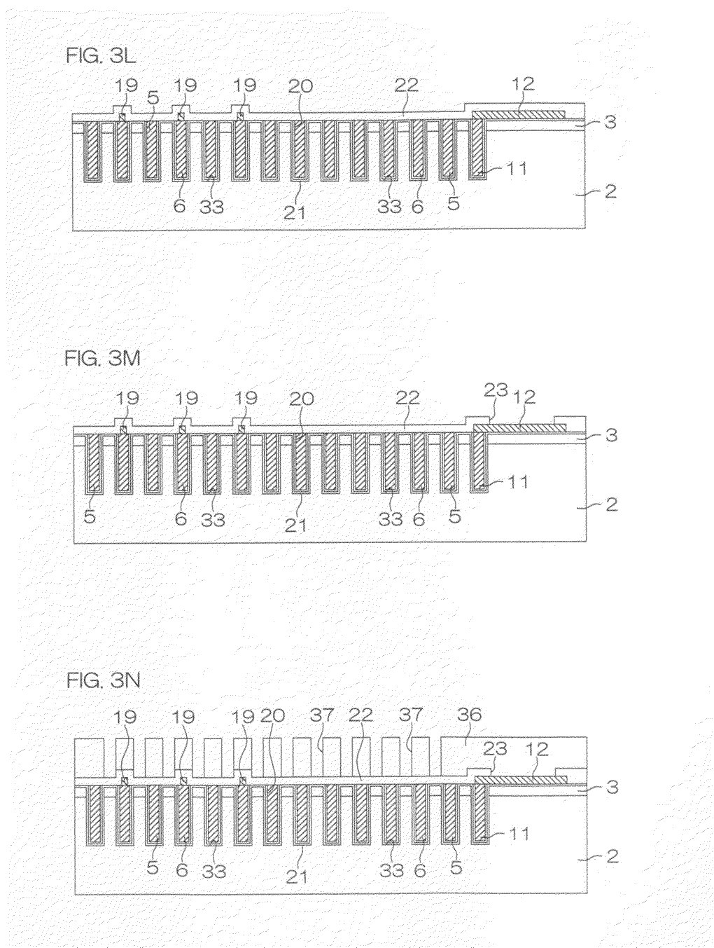

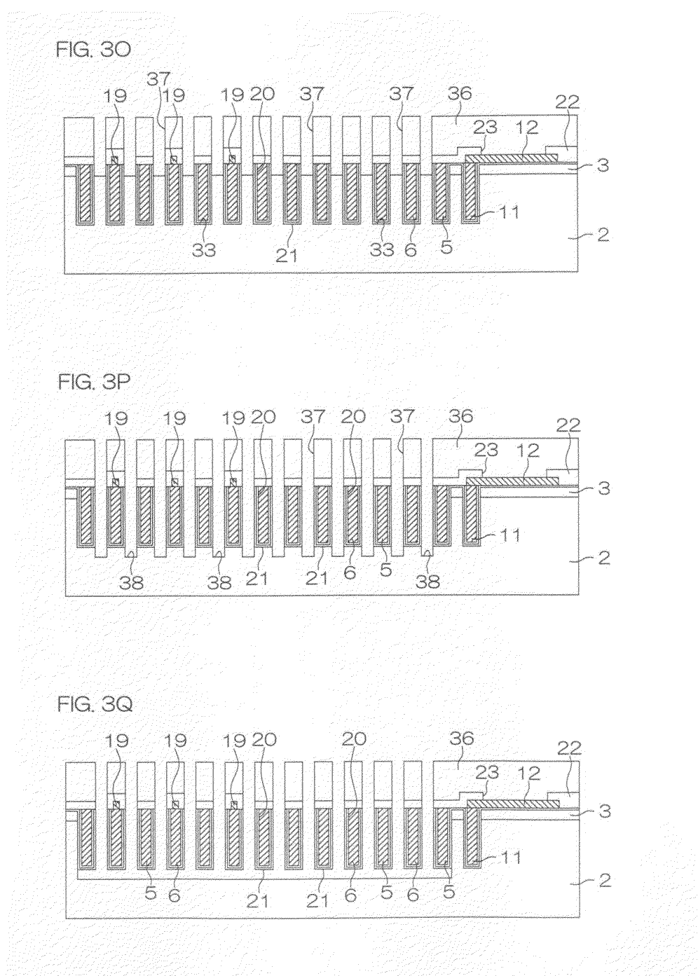

FIGS. 3A to 3Q are schematic sectional views successively showing the steps of manufacturing the acceleration sensor 1 shown in FIG. 2.

In the manufacturing steps for the acceleration sensor 1, the overall region of the surface of the silicon substrate 2 is first oxidized by thermal oxidation, and a silicon oxide layer 31 is formed as the surface layer portion of the silicon substrate 2, as shown in FIG. 3A.

Then, a resist pattern 32 is formed on the silicon oxide layer 31 by photolithography, as shown in FIG. 3B.

Then, the silicon oxide layer 31 is selectively removed by etching through the resist pattern 32 serving as a mask, as shown in FIG. 3C. Consequently, the silicon oxide layer 31 forms the insulating layer 3.

Then, trenches 33 are formed in the silicon substrate 2 by deep RIE (Reactive Ion Etching) through the resist pattern 32 serving as a mask, more specifically by a Bosch process, as shown in FIG. 3D. In the Bosch process, a step of etching the silicon substrate 2 with SF₆ (sulfur hexafluoride) and a step of forming a protective film on the etched surfaces with C₄F₈ (perfluorocyclobutane) are alternately repeated. Thus, the silicon substrate 2 can be etched at a high aspect ratio, while undulate irregularities referred to as scallops are formed on the etched surfaces (the side surfaces of the trenches 33).

Thereafter the resist pattern 32 is removed by ashing, as shown in FIG. 3E.

Then, the insulating film 21 is formed on the overall region of the surface of the silicon substrate 2 including the inner surfaces of the trenches 33 by thermal oxidation or PECVD (Plasma Enhanced Chemical Vapor Deposition), as shown in FIG. 3F.

Thereafter the barrier film 20 is formed on the insulating film 21 by sputtering, as shown in FIG. 3G.

After the formation of the barrier film 20, a deposition layer 34 of W employed as the material for the fixed electrodes 5 and the movable electrodes 6 is formed on the barrier film 20 by plating or CVD, as shown in FIG. 3H. The deposition layer 34 is formed with a thickness for completely filling up the trenches 33.

Then, portions of the deposition layer 34 located outside the trenches 33 are removed by etch-back, as shown in FIG. 3I. Consequently, W (the deposition layer 34) is embedded in the trenches 33, to provide the fixed electrodes 5, the movable electrodes 6, the coupling portions 7, 10, 13 and 16 and the drawn portions 8, 11, 14 and 17 made of W. Further, portions of the barrier film 20 located outside the trenches 33 are also removed by etch-back, along with those of the deposition layer 34. Therefore, the upper surfaces of the fixed electrodes 5, the movable electrodes 6, the coupling portions 7, 10, 13 and 16 and the drawn portions 8, 11, 14 and 17 are generally flush with the surface of the insulating film 21 exposed outside the trenches 33.

Thereafter a metal film 35 made of the material for the pads 9, 12, 15 and 18 is formed on the overall region of the silicon substrate 2 by sputtering, as shown in FIG. 3J.

Then, the metal film 35 is patterned by photolithography and etching, for forming the pads 9, 12, 15 and 18 while leaving the metallic materials 19 (the metal film 35) on the movable electrodes 6Z, as shown in FIG. 3K.

Thereafter the surface protective film 22 is formed on the overall region of the silicon substrate 2 by PECVD, as shown in FIG. 3L.

Then, the openings 23 for exposing the pads 9, 12, 15 and 18 are formed in the surface protective film 22 by photolithography and etching, as shown in FIG. 3M.

After the formation of the openings 23, a resist pattern 36 is formed on the surface protective film 22 by photolithography, as shown in FIG. 3N. The resist pattern 36 has openings 37 opposed to the spaces between the fixed electrodes 5 and the movable electrodes 6 respectively.

After the formation of the resist pattern 36, portions of the surface protective film 22 exposed through the openings 37 are removed by etching, as shown in FIG. 3O. Due to the selective removal of the surface protective film 22, the insulating layer 3 is partially exposed through the openings 37. Then, the portions of the insulating layer 3 exposed through the openings 37 are removed by etching. Consequently, the surface of the silicon substrate 2 is partially exposed through the openings 37.

Thereafter the portions of the silicon substrate 2 exposed through the openings 37 are dug down in the thickness direction by anisotropic deep RIE, as shown in FIG. 3P. Thus, the silicon substrate 2 is partially removed from the spaces between the fixed electrodes 5 and the movable electrodes 6, and trenches 38 are formed between the fixed electrodes 5 and the movable electrodes 6 respectively. The trenches 38 are formed with such a depth that the bottom portions thereof are positioned below the fixed electrodes 5 and the movable electrodes 6.

Then, portions of the silicon substrate 2 located under the fixed electrodes 5 and the movable electrodes 6 are removed through the trenches 38 by isotropic deep RIE, as shown in FIG. 3Q. Thus, the recess 4 is formed in the silicon substrate 2, and the fixed electrodes 5 and the movable electrodes 6 float up from the silicon substrate 2. After the formation of the recess 4, the resist pattern 36 is removed by ashing, and the acceleration sensor 1 shown in FIG. 2 is obtained.

In the acceleration sensor 1, as hereinabove described, the recess 4 is formed in the silicon substrate 2, and the fixed electrodes 5 and the movable electrodes 6 are arranged in the recess 4. The fixed electrodes 5 and the movable electrodes 6 are made not of the silicon material forming the silicon substrate 2 but of tungsten, and not formed by patterning the silicon substrate 2. Therefore, the silicon substrate 2 may not be highly conductive. Thus, the acceleration sensor 1 can be manufactured with the silicon substrate 2 of low conductivity (high resistance) doped with no impurity, without employing an SOI substrate including a highly conductive silicon layer.

The silicon substrate 2 is not highly conductive, whereby the region provided with the fixed electrodes 5 and the movable electrodes 6 may not be isolated from the periphery thereof. Therefore, no isolation layer is required for such isolation. Consequently, the size of the acceleration sensor 1 can be reduced by that occupied by the isolation layer. Further, a step for forming the isolation layer can be omitted, and the manufacturing steps for the acceleration sensor 1 can be simplified. In addition, no photomask for forming the isolation layer is required, whereby the number of photomasks employed for manufacturing the acceleration sensor 1 can be reduced.

The side surfaces of the fixed electrodes 5 and the movable electrodes 6 are covered with the insulating film 21, whereby a short circuit resulting from contact between the fixed electrodes 5 and the movable electrodes 6 can be prevented.

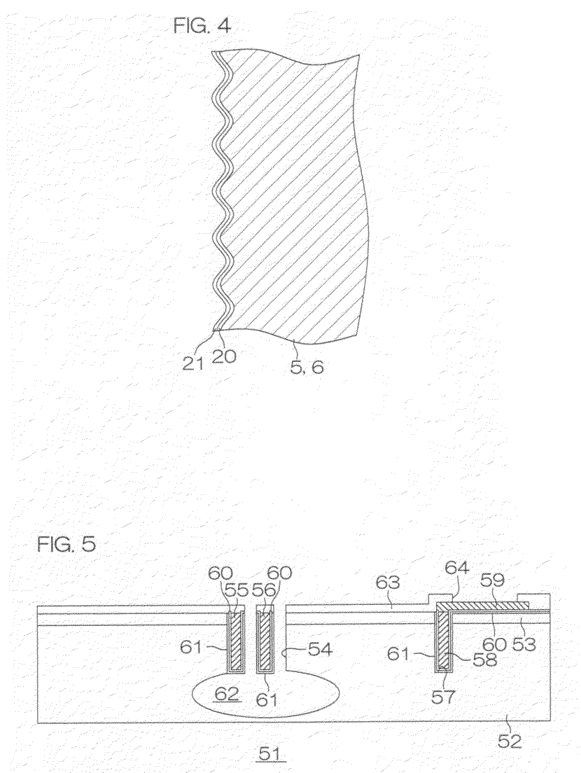

In the manufacturing steps for the acceleration sensor 1, the trenches 33 are formed in the silicon substrate 2 by the Bosch process, and the fixed electrodes 5 and the movable electrodes 6 are embedded in the trenches 33 through the insulating film 21. In the Bosch process, the undulate irregularities referred to as scallops are formed on the side surfaces of the trenches 33. Therefore, undulate irregularities corresponding to the scallops are necessarily formed on the side surface of the insulating film 21 covering the fixed electrodes 5 and the movable electrodes 6, as shown in FIG. 4. The irregularities on the side surface of the insulating film 21 function as stabilizers for the movable electrodes 6 when the movable electrodes 6 are displaced (vibrated). Consequently, the movable electrodes 6 can be prevented from sticking to the fixed electrodes 5.

FIG. 5 is a schematic sectional view of a silicon microphone according to a second embodiment of the present invention.

A silicon microphone 51 according to the second embodiment is a sensor (an MEMS sensor) manufactured by the MEMS technique.

The silicon microphone 51 includes a silicon substrate 52 quadrangular in plan view. The silicon substrate 52 is a high-resistance (low-conductivity) substrate doped with no impurity.

An insulating layer 53 made of SiO₂ is formed on a surface layer portion of the silicon substrate 52.

A recess 54 quadrangular in plan view is formed in the silicon substrate 52. The recess 54 is dug down from the surface of the insulating layer 53.

A fixed electrode 55 (a back plate) and a movable electrode 56 (a diaphragm) are provided in the recess 54. The fixed electrode 55 and the movable electrode 56 are made of W (tungsten), and provided in the form of plates extending in the depth direction of the recess 54 and a direction orthogonal thereto respectively. The fixed electrode 55 and the movable electrode 56 are opposed to each other in an X-axis direction parallel to the surface of the silicon substrate 52 at a small interval.

Two trenches 57 are formed in the silicon substrate 52. Drawn portions 58 made of the same metallic material as the fixed electrode 55 and the movable electrode 56 are embedded in the trenches 57 respectively. The drawn portions 58 are formed integrally with the fixed electrode 55 and the movable electrode 56 respectively, and connected to pads 59 provided on the insulating layer 53 from under the same. The pads 59 are made of a metallic material (Al, for example), and quadrangular in plan view. FIG. 5 shows only one drawn portion 58 and the pad 59 connected thereto.

The side surfaces and the lower surfaces of the fixed electrode 55, the movable electrode 56 and each drawn portion 58 are covered with a barrier film 60. The barrier film 60 is a multilayer film of Ti (titanium)/TiN (titanium nitride) or that of Ti/W, for example. The outer side of the barrier film 60 is covered with an insulating film 61. The insulating film 61 is made of SiO₂, for example.

In the silicon substrate 52, a sectionally elliptical sound wave reflecting space 62 communicating with the recess 54 is formed under the recess 54 (on the side closer to a base layer of the silicon substrate 52).

A surface protective film 63 is stacked on the silicon substrate 52. The surface protective film 63 is made of SiN (silicon nitride), for example. An opening 64 for individually exposing each pad 59 is formed in the surface protective film 63, so that an external wire (not shown) can be connected to each pad 59 through each opening 64.

In the silicon microphone 51, a sound wave is incident upon the sound wave reflecting space 62 through the recess 54. The sound wave incident upon the sound wave reflecting space 62 is reflected on the inner surface of the sound wave reflecting space 62, and introduced into the movable electrode 56. Thus, the movable electrode 56 is vibrated in the opposed direction to the fixed electrode 55 to change the interval between the fixed electrode 55 and the movable electrode 56, thereby changing the capacitance of a capacitor constituted of the fixed electrode 55 and the movable electrode 56. Due to the change in the capacitance, a current responsive to the change in the capacitance flows to the external wire connected to each pad 59. Thus, the strength and the frequency of the sound wave can be detected on the basis of the value of the current.

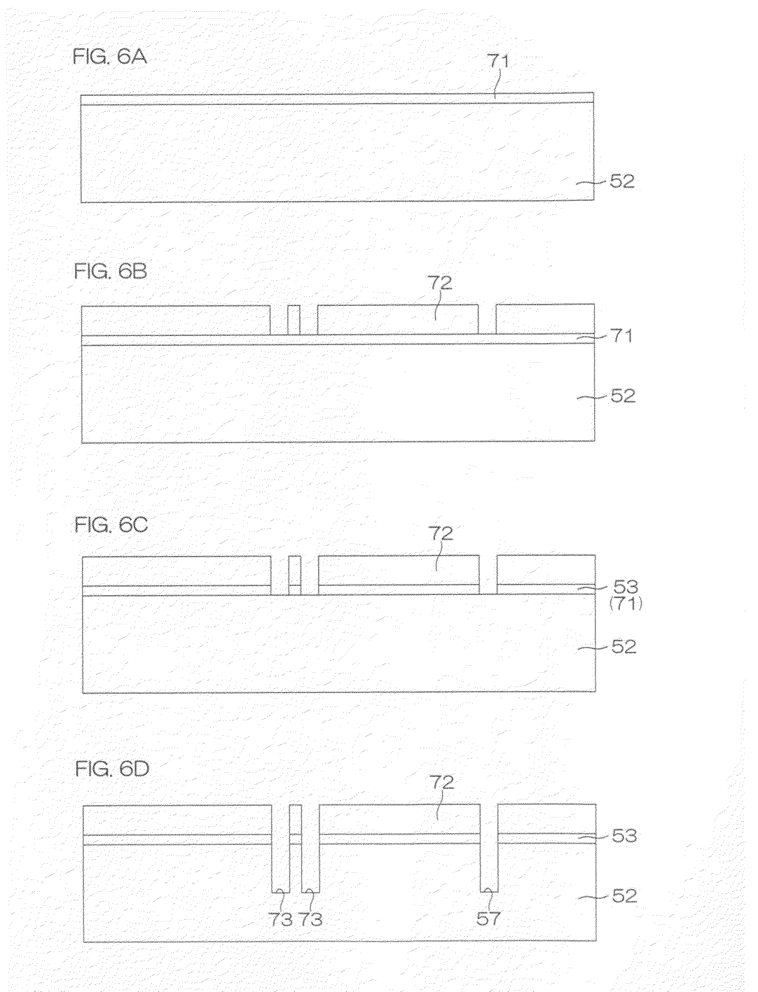

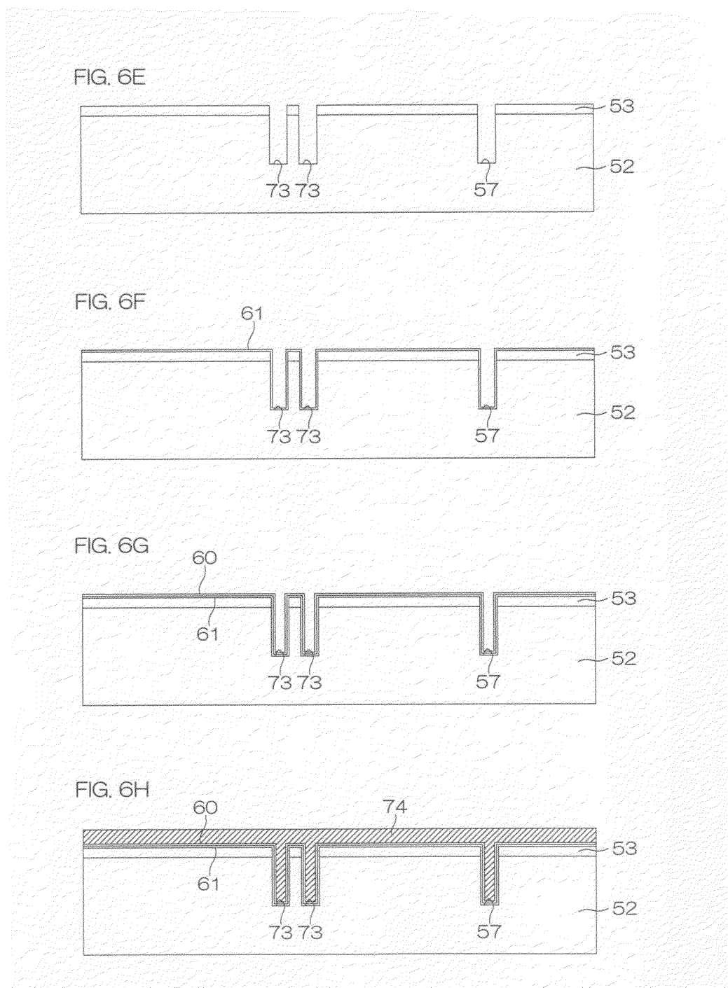

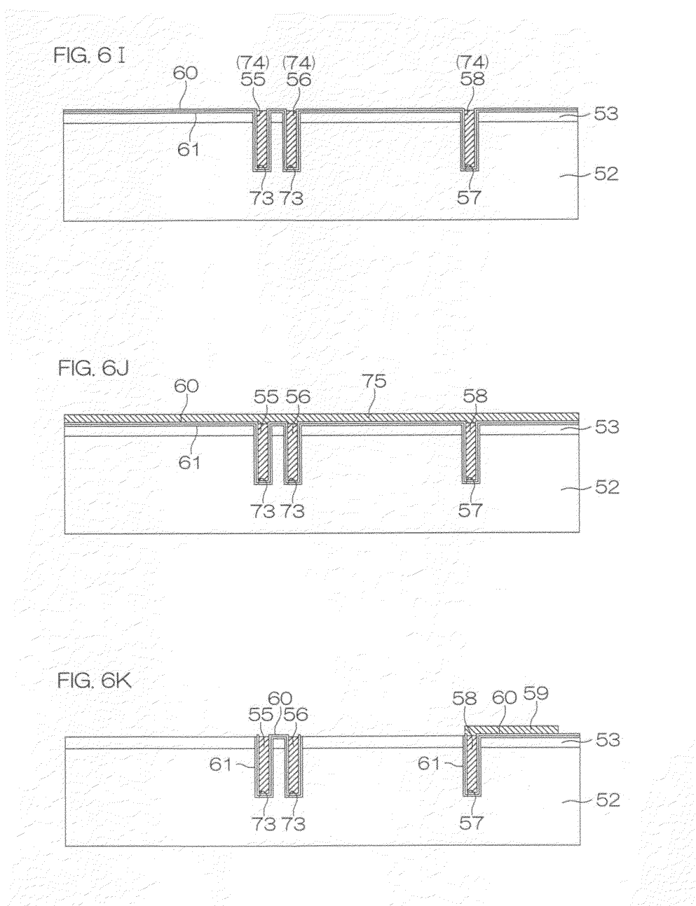

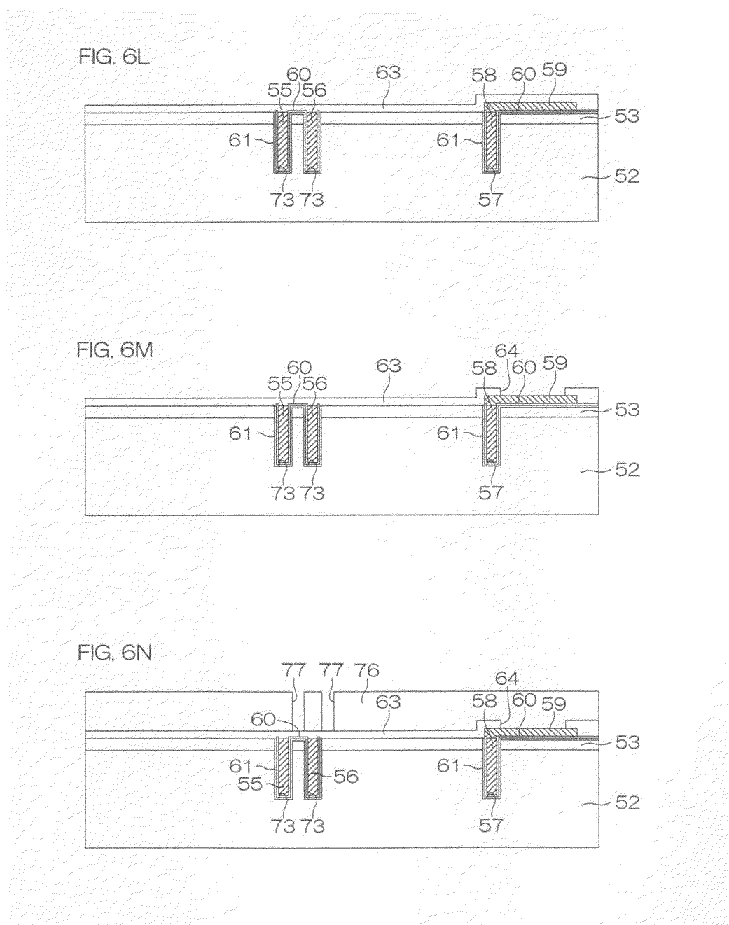

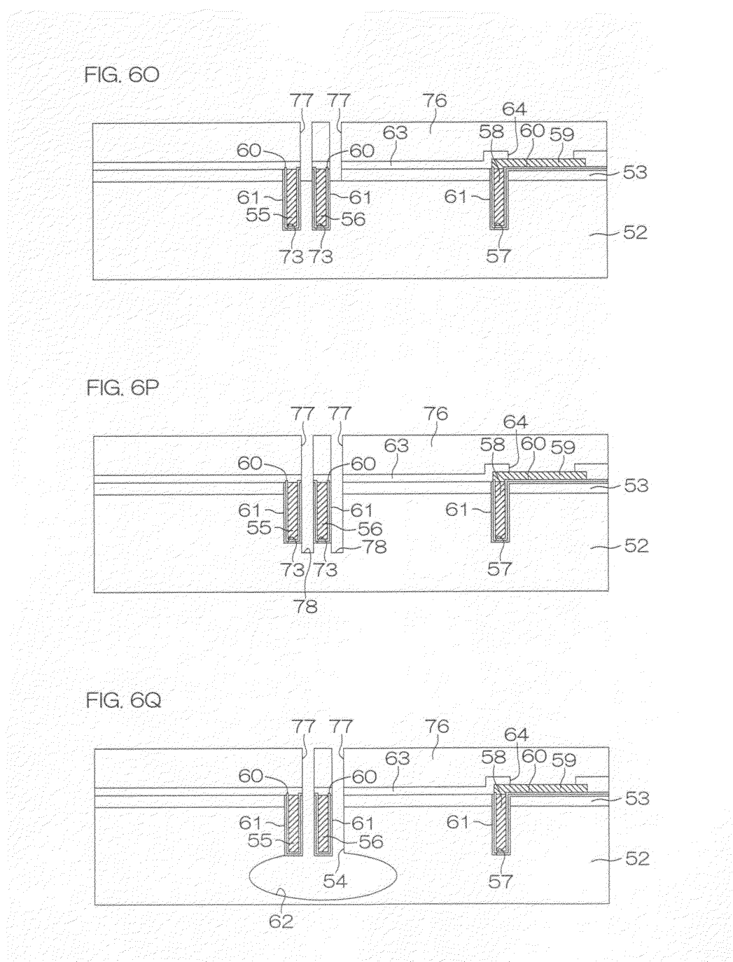

FIGS. 6A to 6Q are schematic sectional views successively showing the steps of manufacturing the silicon microphone 51 shown in FIG. 5.

In the manufacturing steps for the silicon microphone 51, the overall region of the surface of the silicon substrate 2 is first oxidized, and a silicon oxide layer 71 is formed as the surface layer portion of the silicon substrate 52, as shown in FIG. 6A.

Then, a resist pattern 72 is formed on the silicon oxide layer 71 by photolithography, as shown in FIG. 6B.

Then, the silicon oxide layer 71 is selectively removed by etching through the resist pattern 72 serving as a mask, as shown in FIG. 6C. Consequently, the silicon oxide layer 71 forms the insulating layer 53.

Then, trenches 57 and 73 are formed in the silicon substrate 52 by deep RIE through the resist pattern 72 serving as a mask, more specifically by a Bosch process, as shown in FIG. 6D. In the Bosch process, a step of etching the silicon substrate 52 with SF₆ and a step of forming a protective film on the etched surfaces with C₄F₈ are alternately repeated. Thus, the silicon substrate 52 can be etched at a high aspect ratio, while undulate irregularities referred to as scallops are formed on the etched surfaces (the side surfaces of the trenches 57 and 73).

Thereafter the resist pattern 72 is removed by asking, as shown in FIG. 6E.

Then, the insulating film 61 is formed on the overall region of the surface of the silicon substrate 52 including the inner surfaces of the trenches 57 and 73 by thermal oxidation or PECVD (Plasma Enhanced Chemical Vapor Deposition), as shown in FIG. 6F.

Thereafter the barrier film 60 is formed on the insulating film 61 by sputtering, as shown in FIG. 6G.

After the formation of the barrier film 60, a deposition layer 74 of W employed as the material for the fixed electrode 55 and the movable electrode 56 is formed on the barrier film 60 by plating or CVD, as shown in FIG. 6H. The deposition layer 74 is formed with a thickness for completely filling up the trenches 57 and 73.

Then, portions of the deposition layer 74 located outside the trenches 57 and 73 are removed by etch-back, as shown in FIG. 6I. Consequently, W (the deposition layer 74) is embedded in the trenches 73, to provide the fixed electrode 55, the movable electrode 56 and each drawn portion 58 made of W. The upper surfaces of the fixed electrode 55, the movable electrode 56 and each drawn portion 58 are generally flush with the surface of the barrier film 60 exposed outside the trenches 57 and 73.

Thereafter a metal film 75 made of the material for each pad 59 is formed on the overall region of the silicon substrate 52 by sputtering, as shown in FIG. 6J.

Then, the metal film 75 is patterned by photolithography and etching for forming each pad 59, as shown in FIG. 6K. At this time, portions of the barrier film 60 and the insulating film 61 located outside the trenches 57 and 73 are also removed.

Thereafter the surface protective film 63 is formed on the overall region of the silicon substrate 52 by PECVD, as shown in FIG. 6L.

Then, the opening 64 for exposing each pad 59 is formed in the surface protective film 63 by photolithography and etching, as shown in FIG. 6M.

After the formation of the opening 64, a resist pattern 76 is formed on the surface protective film 63 by photolithography, as shown in FIG. 6N. The resist pattern 76 has openings 77 opposed to the space between the fixed electrode 55 and the movable electrode 56 and a region of a prescribed width opposite thereto respectively. In other words, the openings 77 are opposed to regions on both sides of the movable electrode 56 in the X-axis direction respectively.

After the formation of the resist pattern 76, portions of the surface protective film 63 exposed through the openings 77 are removed by etching, as shown in FIG. 6O. Due to the selective removal of the surface protective film 63, the insulating layer 53 is partially exposed through the openings 77. Then, the portions of the insulating layer 53 exposed through the openings 77 are removed by etching. Consequently, the surface of the silicon substrate 52 is partially exposed through the openings 77.

Thereafter the portions of the silicon substrate 52 exposed through the openings 77 are dug down in the thickness direction by anisotropic deep RIE, as shown in FIG. 6P. Thus, the silicon substrate 52 is removed from the space between the fixed electrode 55 and the movable electrode 56, and a trench 78 is formed between the fixed electrode 55 and the movable electrode 56. The trench 78 is formed in such a depth that the bottom portion thereof is positioned below the fixed electrode 55 and the movable electrode 56.

Then, portions of the silicon substrate 52 located under the fixed electrode 55 and the movable electrode 56 are removed through the trench 78 by isotropic deep RIE, as shown in FIG. 6Q. Thus, the recess 54 is formed so that the fixed electrode 55 and the movable electrode 56 are arranged therein, while the sound wave reflecting space 62 communicating with the recess 54 is formed. After the formation of the recess 54 and the sound wave reflecting space 62, the resist pattern 76 is removed by ashing, and the silicon microphone 51 shown in FIG. 5 is obtained.

In the silicon microphone 51, as hereinabove described, the recess 54 is formed in the silicon substrate 52, and the fixed electrode 55 and the movable electrode 56 are arranged in the recess 54. The fixed electrode 55 and the movable electrode 56 are made not of the silicon material forming the silicon substrate 52 but of tungsten, and not formed by patterning the silicon substrate 52. Therefore, the silicon substrate 52 may not be highly conductive. Thus, the silicon microphone 51 can be manufactured with the silicon substrate 52 of low conductivity (high resistance) doped with no impurity, without employing an SOI substrate including a highly conductive silicon layer.

The silicon substrate 52 is not highly conductive, whereby the region provided with the fixed electrode 55 and the movable electrode 56 may not be isolated from the periphery thereof. Therefore, no isolation layer is required for such isolation. Consequently, the size of the silicon microphone 51 can be reduced by that occupied by the isolation layer. Further, a step for forming the isolation layer can be omitted, and the manufacturing steps for the silicon microphone 51 can be simplified. In addition, no photomask for forming the isolation layer is required, whereby the number of photomasks employed for manufacturing the silicon microphone 51 can be reduced.

The side surfaces of the fixed electrode 55 and the movable electrode 56 are covered with the insulating film 61, whereby a short circuit resulting from contact between the fixed electrode 55 and the movable electrode 56 can be prevented.

In the manufacturing steps for the silicon microphone 51, the trenches 73 are formed in the silicon substrate 52 by the Bosch process, and the fixed electrode 55 and the movable electrode 56 are embedded in the trenches 73 through the insulating film 61. In the Bosch process, undulate irregularities referred to as scallops are formed on the side surfaces of the trenches 73. Therefore, undulate irregularities corresponding to the scallops are necessarily formed on the side surface of the insulating film 61 covering the fixed electrode 55 and the movable electrode 56, as shown in FIG. 4. The irregularities on the side surface of the insulating film 61 function as stabilizers for the movable electrode 56 when the movable electrode 56 is displaced (vibrated). Consequently, the movable electrode 56 can be prevented from sticking to the fixed electrode 55.

In the silicon microphone 51, further, the sound wave reflecting space 62 communicating with the recess 54 is formed under the recess 54, whereby the sound wave incident upon the sound wave reflecting space 62 through the recess 54 can be reflected on the inner surface thereof, and the reflected wave can be excellently introduced into the movable electrode 56. Therefore, the sound wave can be excellently detected.

The material for the fixed electrodes 5 and 55 and the movable electrodes 6 and 56 may be a metallic material other than W, i.e., a plating metal such as Au (gold), Cu (copper) or Ni (nickel) or a CVD metal such as TiN (titanium nitride).

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2009-020990 filed with the Japan Patent Office on Jan. 30, 2009, the disclosure of which is incorporated herein by reference.

What is claimed is:

1. An MEMS sensor comprising:
a substrate made of a silicon material, having a recess dug down from the surface thereof;
a fixed electrode made of a metallic material, arranged in the recess and fixed to the substrate; and
a movable electrode made of a metallic material, arranged in the recess to be opposed to the fixed electrode and provided to be displaceable with respect to the fixed electrode.

2. The MEMS sensor according to claim 1, wherein
the fixed electrode and the movable electrode are in the form of plates extending in the depth direction of the recess and a direction orthogonal thereto, and opposed to each other in a direction parallel to the surface of the substrate.

3. The MEMS sensor according to claim 1, wherein
a surface of the fixed electrode opposed to the movable electrode and a surface of the movable electrode opposed to the fixed electrode are covered with an insulating film.

4. The MEMS sensor according to claim 3, wherein
undulate irregularities are formed on the surface of the insulating film.

5. The MEMS sensor according to claim 1, wherein
the movable electrode includes a first movable electrode displaced in an opposed direction to the fixed electrode for detecting acceleration in the opposed direction.

6. The MEMS sensor according to claim 1, wherein
the movable electrode includes a second movable electrode displaced in the depth direction of the recess for detecting acceleration in the depth direction.

7. The MEMS sensor according to claim 6, wherein
a metallic material is bonded to a surface of the second movable electrode opposite to a surface opposed to the bottom surface of the recess, and
the position of the second movable electrode deviates from the fixed electrode in the depth direction.

8. The MEMS sensor according to claim 1, wherein
the movable electrode is displaced in an opposed direction to the fixed electrode, for detecting a sound wave incident upon the recess.

9. The MEMS sensor according to claim 8, wherein
a sound wave reflecting space communicating with the recess is formed on a side closer to a base layer of the substrate than the recess.

10. The MEMS sensor according to claim 1, wherein
the materials for the fixed electrode and the movable electrode are tungsten.
